(19) United States
(12) Patent Application Publication
(10) Pub. No.: US 2010/0170786 A1
(43) Pub. Date: Jul. 8, 2010

(54) REFURBISHED SPUTTERING TARGET AND METHOD FOR MAKING THE SAME

(75) Inventors: Tzu-Wen WANG, Tainan (TW); Chih-Yao CHAN, Tainan (TW); Hao-Chia LIAO, Tainan (TW)

Correspondence Address: PATENTTM.US, P. O. BOX 82788, PORTLAND, OR, 97282-0788, US

(73) Assignee: SOLAR APPLIED MATERIALS TECHNOLOGY CORP., Tainan (TW)

(21) Appl. No.: 12/498,148

(22) Filed: Jul. 6, 2009

(30) Foreign Application Priority Data
Jan. 7, 2009 (TW) 098100315

(51) Int. Cl. C23C 14/34; B22F 7/04

(52) U.S. Cl. 204/298.13; 419/8; 204/298.12

(57) ABSTRACT

A method for making a refurbished sputtering target has steps of providing a spent target with a backside, an eroded side and a rim; mechanically pre-treating the backside of the spent target; applying powder material that has the same composition as the spent target to form a powder-filled layer; and sequentially pre-pressing and sintering the spent target with the powder-filled layer to obtain the refurbished sputtering target. Therefore, a percentage of the spent target is reduced by mechanically treating the backside of the spent target, so the refurbished sputtering target has a consistent quality.

### BACKGROUND OF THE INVENTION

1. Field of Invention

The present invention relates to a method for making a refurbished sputtering target, and more particularly to a method for making a refurbished sputtering target with reduced percentage of spent target in the refurbished sputtering target.

2. Description of the Related Art

Physical vapor deposition (PVD) is broadly used for depositing a thin film for semiconductors, hard discs, optical discs or the like and uses a sputtering target. The sputtering target, however, is usually only consumed to 25˜40% or even less after a sputtering procedure and a spent target is obtained. The spent target will be discarded, so cost of a sputtering target cannot be reduced.

When a sputtering target contains a large amount of noble metal, the sputtering target will be crushed, re-melted and undergo electrolytic or chemical refining to retrieve powder material for making another new sputtering target. Nevertheless, refining the sputtering target is a complex procedure and increases a cost for making a whole new sputtering target. Therefore, relevant industries focus on seeking a method for making a refurbished sputtering target with reduced cost.

Many conventional methods for making refurbished sputtering targets focus on improving a sintering process.

JP 63-093859 discloses repeatedly immersing a surface of a spent target in acid and cleaning the spent target; then filling an eroded side of the spent target with powder material that has the same composition as the spent target; and sintering the spent target with powder material by using thermal pressing technology in a vacuum to obtain a refurbished sputtering target.

JP 24-225091 and JP 20-256843 respectively disclose methods for making refurbished targets using discharge plasma sintering and thermal spraying. Nevertheless, those methods require expensive equipment, which increases costs.

U.S. Pat. No. 7,175,802 discloses a method for making a refurbished target using hot isostatic pressing (HIP), in which a spent target is used as a support material that will not be sputtered. An eroded side of the spent target is filled with powder material that has the same composition as or different composition from the spent target. This patent does not explain, however, why the spent target will not be sputtered and does not discloses how to reduce a percentage of the spent target in the refurbished target.

JP 24-35919 discloses mechanically cutting an eroded side of the spent target to a flat side; and diffusion connecting a new sputtering target on the flat side of the spent target to form a refurbished sputtering target. But in the diffusion connecting, stress occurred on an interface between the new sputtering target, which may cause abnormal growth or breaks in grains and lead to unpredictable sputtering performance.

By using the conventional methods, after many refurbishing process, the spent target initially provided for making a refurbished sputtering target at the first time is reused and cannot be removed in each new refurbished sputtering target, in which the spent target has been sintered and pressed for many times with poor physical property, so the refurbished sputtering target cannot have improved quality and may have worse and worse quality.

The present invention provides a method for making a refurbished sputtering target to mitigate or obviate the aforementioned shortcomings.

### SUMMARY OF THE INVENTION

The primary objective of the present invention is to provide a method for making a refurbished sputtering target with reduced percentage of spent target in the refurbished sputtering target.

To achieve the objective, the method for making a refurbished sputtering target in accordance with the present invention comprises providing a spent target with a backside, an eroded side and a rim; mechanically pre-treating the backside of the spent target; applying powder material that has the same composition as the spent target to form a powder-filled layer; and sequentially pre-pressing and sintering the spent target with the powder-filled layer to obtain the refurbished sputtering target.

Therefore, a percentage of the spent target is reduced by mechanically treating the backside of the spent target, so the refurbished sputtering target has a consistent quality.

Other objectives, advantages and novel features of the invention will become more apparent from the following detailed description when taken in conjunction with the accompanying drawings.

### BRIEF DESCRIPTION OF THE DRAWINGS

FIG. 1 is a flow chart of a method for making a refurbished sputtering target in accordance with the present invention;

FIGS. 2A to 2D are sequential cross sectional side views showing the method for making the refurbished sputtering target in FIG. 1;

FIG. 3 is a perspective view of a spent target used for making a refurbished sputtering target in accordance with the present invention;

FIG. 4 is a perspective view of a refurbished sputtering target in accordance with the present invention before mechanical treatment;

FIG. 5 is perspective view of a refurbished sputtering target in accordance with the present invention;

FIG. 6A is a graphical representation of ultrasonic testing of the spent target without being pre-pressed;

FIG. 6B is a graphical representation of ultrasonic testing of the spent target that has been pre-pressed.

FIG. 7 is a graphical representation of ultrasonic testing showing a refurbished sputtering target with ruthenium (Ru) made by a method shown in example 1; and

FIG. 8 is a graphical representation of ultrasonic testing showing a conventional sputtering target made by sintering powder material without containing any spent target.

### DETAILED DESCRIPTION OF THE INVENTION

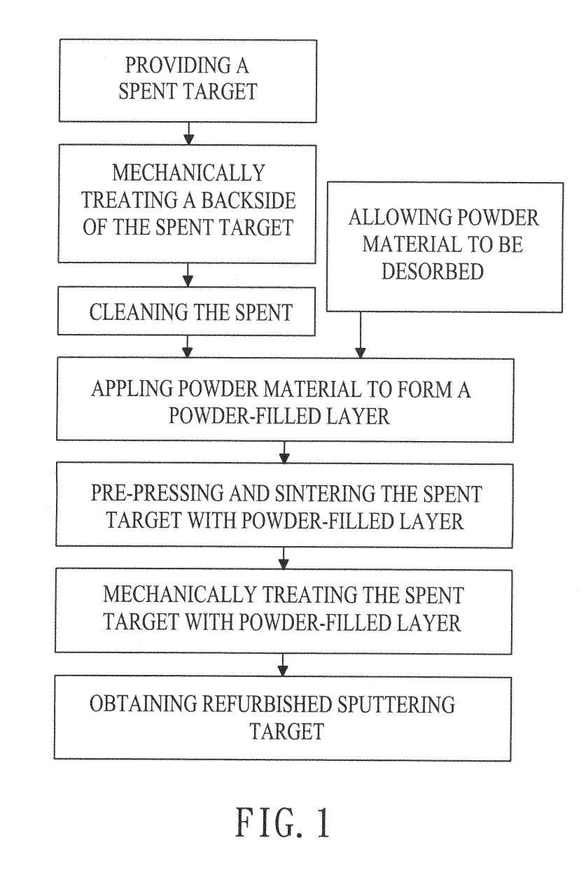

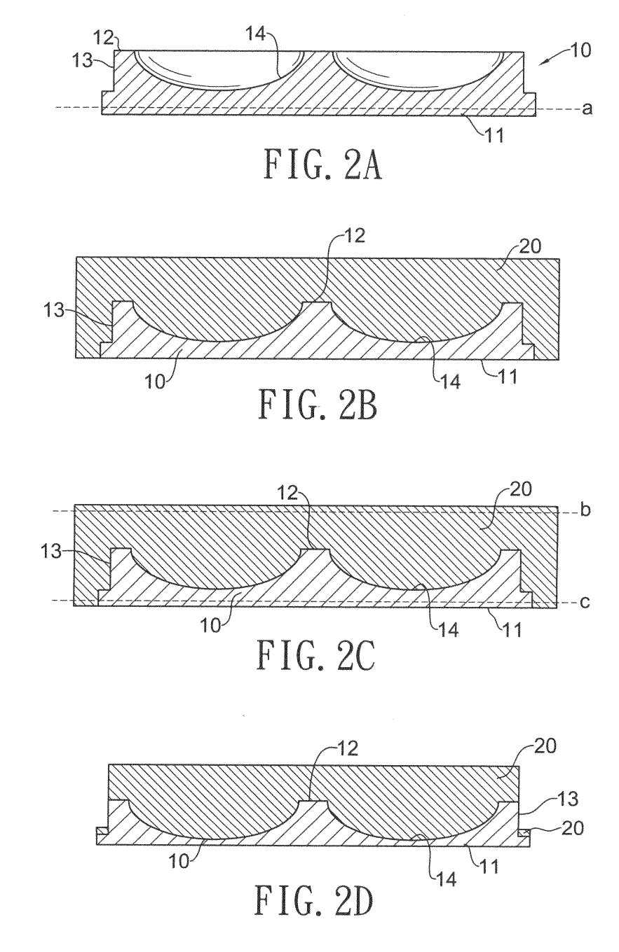

With reference to FIGS. 1 and 2, a method for making a refurbished sputtering target in accordance with the present invention has steps of providing a spent target (10) with a backside (11), an eroded side (12) and a rim (13); mechanically pre-treating the backside (11) of the spent target (10); cleaning the spent target (10), applying powder material that has the same composition as the spent target (10) to form a powder-filled layer (20); sequentially pre-pressing and sintering the spent target (10) with the powder-filled layer (20); and mechanically treating the spent target (10) with the powder-filled layer (20) to obtain the refurbished sputtering target.

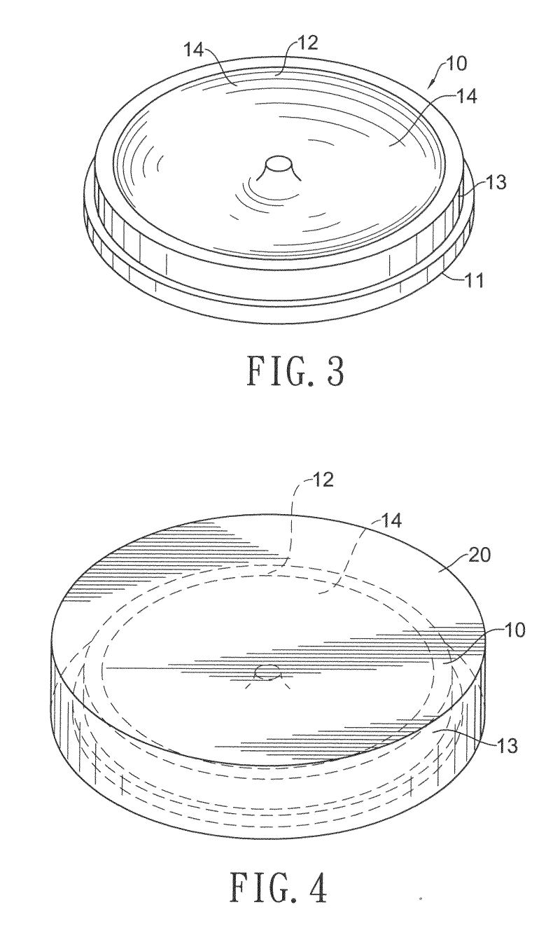

With further reference to FIGS. 2A and 3, in the step of providing a spent target (10), the spent target (10) has a backside (11), an eroded side (12) and a rim (13). The eroded side (12) has at least one depleted region (14). The depleted region (14) is formed in the eroded side (12) when the spent target (10) was previously sputtered. The spent target (10) contains at least one precious metal such as ruthenium (Ru), platinum (Pt), palladium (Pd), silver (Ag), gold (Au), rhodium (Rh), iridium (Ir), osmium (Os) or an alloy thereof.

The step of mechanically pre-treating the backside (11) of the spent target (10) is shown as a dotted line (a) in FIG. 2A and comprises removing the backside (11) with a predetermined thickness. The predetermined thickness depends on volume of the spent target (10) and a desired thickness of the refurbished sputtering target. The step of mechanically pre-treating the backside (11) comprises cutting, polishing, wire-cutting the backside (11) or a combination thereof.

The step of cleaning the spent target (10) comprises cleaning the backside (11), the eroded side (12), the rim (13) and the depleted region (14) of the spent target (10) using at least one manner of ultrasonic cleaning, etch cleaning, carbon dioxide (CO₂) spray cleaning, supercritical fluid cleaning, plasma cleaning or the like.

With further reference to FIGS. 2B and 4, the step of applying powder material that has the same composition with the spent target (10) comprises applying the powder material in the depleted region (14) and on the eroded side (12) and the rim (13) to form a powder-filled layer (20). Before the step of applying powder material, a step of allowing powder material to be desorbed at a high temperature in a vacuum is provided. Preferably, the powder material is desorbed at 800˜1200° C. in a vacuum of 10⁻¹˜10⁻⁵ torr for less than 5 hours.

In the step of sequentially pre-pressing and sintering the spent target (10) with the powder-filled layer (20), sintering comprises hot-press sintering, hot isostatic press (HIP) sintering, spark plasma sintering or a combination thereof.

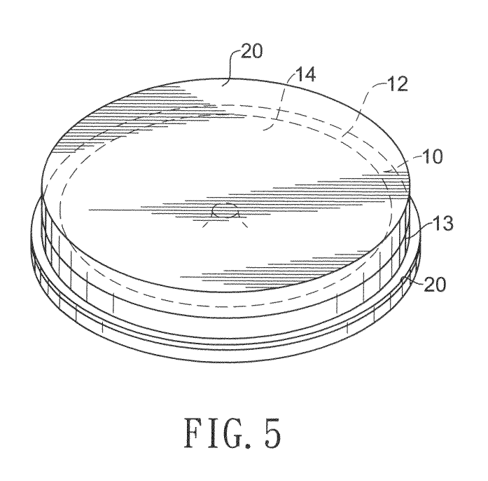

With further reference to FIG. 2C, the step of mechanically treating the spent target (10) with the powder-filled layer (20) is shown as dotted lines (b) and (c) and comprises mechanically treating the backside (11) of the spent target (10) and a front surface and an edge of the powder-filled layer (20) by cutting, polishing, wire-cutting or a combination thereof to obtain the refurbished sputtering target with a desired size as shown in FIGS. 2D and 5.

Ultrasonic testing (UT) is used to test sputtering targets, where different density is represented by color shade.

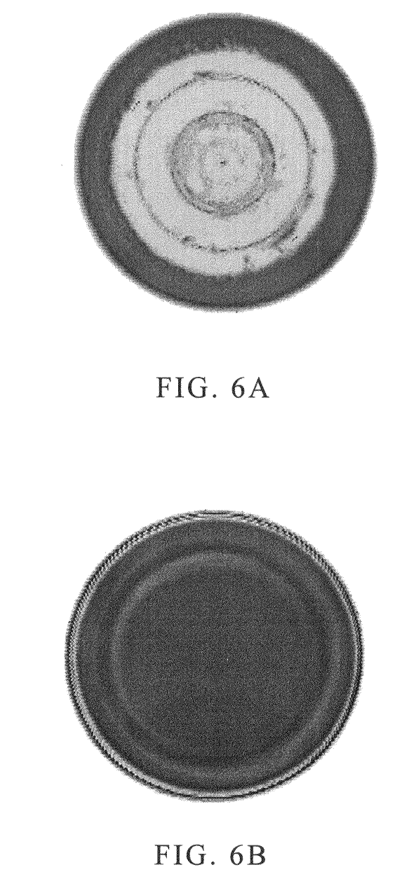

As shown in FIG. 6A, if the spent target (10) and the powder-filled layer (20) are not pre-pressed, the powder material cannot be sintered densely and uniformly. The refurbished sputtering target of the present invention has a dense powder-filled layer (20) and a uniform density with the same color as shown in FIG. 6B.

With further reference to FIGS. 2D and 5, a refurbished sputtering target in accordance with the present invention comprises a spent target (10) and a powder-filled layer (20).

The spent target (10) has a mechanical treated backside (11), an eroded side (12) and a rim (13). The eroded side (12) has at least one depleted region (14). The depleted region (14) is formed in the eroded side (12).

The spent target (10) contains precious metal. Preferably, the precious metal is selected from the group consisting of ruthenium (Ru), platinum (Pt), palladium (Pd), silver (Ag), gold (Au), rhodium (Rh), iridium (Ir), osmium (Os) or an alloy thereof.

The powder-filled layer (20) is at least formed on the eroded side (12), is filled in the depleted region (14), allows at least the backside (11) of the spent target (10) to expose from a bottom of the powder-filled layer (20) and has a composition that is the same as the spent target (10).

After refurbishing the spent target (10) multiple times by using the method of the present invention, the spent target (10) used the first time keeps away from an eroded surface of the refurbished sputtering target and a percentage of the spent target is reduced by mechanically treating the backside (11) of the spent target (10). Therefore, the refurbished sputtering target has a consistent quality with decreased cost.

### EXAMPLE

The following examples present a detailed procedure of the method for making the refurbished sputtering target of the present invention. Such examples are illustrative only, and no limitation on the present invention is to be thereby realized.

### Example 1

A spent target containing ruthenium (Ru) was provided and a backside of the spent target was mechanically treated by cutting to a predetermined thickness. Then, the spent target was cleaned by carbon dioxide spraying to remove micro-scaled particles and dust from the spent target. Sequentially, powder material having the same composition as the spent target was desorbed at 800˜1200° C. in a vacuum for less than 5 hours. The spent target was put into a mold and the powder material was applied on an eroded surface and a rim of the spent target and in a depleted region of the spent target to form a powder-filled layer. The spent target and the powder-filled layer was pre-pressed and hot-press sintered at 1200˜1400° C., 300˜450 bar for 100˜400 min to obtain a refurbished sputtering target.

The refurbished sputtering target in example 1 was tested by UT and compared with a conventional sputtering target.

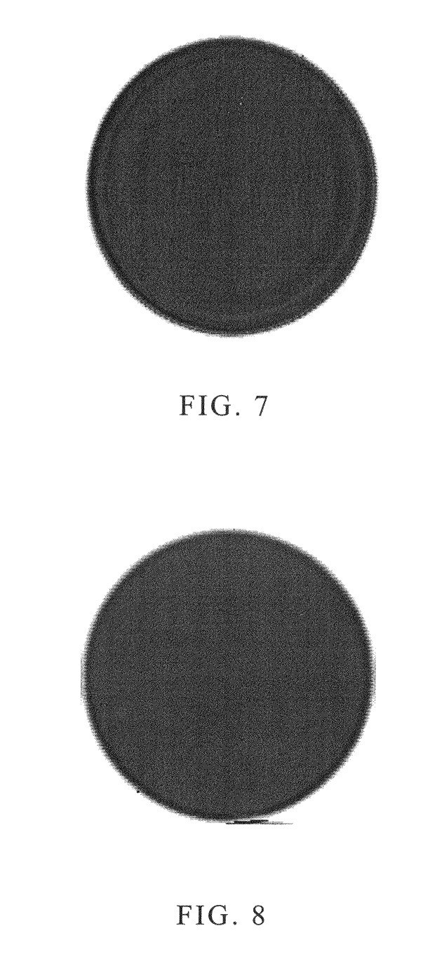

FIG. 7 shows the refurbished sputtering target in example 1, which has a relative density (R.D.) value of 99.8%. FIG. 8 shows a conventional sputtering target made by sintering powder material without containing any spent target, which has an R.D. value of 99.5%. Accordingly, the refurbished sputtering target of the present invention has a similar R.D. value compared with the conventional sputtering target while using less powder material so is lower cost.

### Example 2

A spent target containing ruthenium (Ru) was provided and a backside of the spent target was mechanically treated by wire-cutting to a predetermined thickness. Then, the spent target was cleaned by ultrasonic cleaning to remove micro-scaled particles and dust from the spent target. Sequentially, powder material having the same composition as the spent target was desorbed at 800˜1200° C. in a vacuum for less than 5 hours. The spent target was put into a mold and the powder material was applied on an eroded surface and a rim of the spent target and in a depleted region of the spent target to form a powder-filled layer. The spent target and the powder-filled layer was-pre-pressed and thermal isostatic press sintered at 1000˜1500° C., 20000˜35000 psi for 100˜300 min to obtain a refurbished sputtering target.

### Example 3

A spent target containing ruthenium (Ru) was provided and a backside of the spent target was mechanically treated by cutting to a predetermined thickness. Then, the spent target was cleaned by carbon dioxide supercritical fluid to remove micro-scaled particles and dust from the spent target. Sequentially, powder material having the same composition as the spent target was desorbed at 800˜1200° C. in a vacuum for less than 5 hours. The spent target was put into a mold and the powder material was applied on an eroded surface and a rim of the spent target and in a depleted region of the spent target to form a powder-filled layer. The spent target and the powder-filled layer was pre-pressed and hot-press sintered at 1200˜1400° C., 300˜450 bar for 100˜400 min and thermal isostatic press sintered at 1000˜1500° C., 20000˜35000 psi for 100˜300 min to obtain a refurbished sputtering target.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A method for making a refurbished sputtering target comprising steps of:
providing a spent target with a backside, an eroded side and a rim and the eroded side having at least one depleted region;
mechanically pre-treating the backside of the spent target;
applying powder material on the eroded side and the rim and in the depleted region and the powder material having the same composition as the spent target to form a powder-filled layer; and
sequentially pre-pressing and sintering the spent target with the powder-filled layer to obtain the refurbished sputtering target.

2. The method as claimed in claim 1, wherein the step of mechanically pre-treating comprises cutting, polishing, wire-cutting or a combination thereof.

3. The method as claimed in claim 2, further comprising a step of mechanically treating the spent target with the powder-filled layer after the step of pre-pressing and sintering to obtain a refurbished sputtering target with a desired size.

4. The method as claimed in claim 3, wherein a step of mechanically treating the spent target with the powder-filled layer comprises mechanically treating the backside of the spent target and a front surface and an edge of the powder-filled layer by cutting, polishing, wire-cutting or a combination thereof.

5. The method as claimed in claim 1, further comprising a step of cleaning the spent target before the step of mechanically pre-treating the backside of the spent target.

6. The method as claimed in claim 5, wherein the step of cleaning comprises ultrasonic cleaning, etch cleaning, carbon dioxide (CO₂) spray cleaning, supercritical fluid cleaning, plasma cleaning or a combination thereof.

7. The method as claimed in claim 4, further comprising a step of cleaning the spent target before the step of mechanically pre-treating the backside of the spent target.

8. The method as claimed in claim 7, wherein the step of cleaning comprises ultrasonic cleaning, etch cleaning, carbon dioxide (CO₂) spray cleaning, supercritical fluid cleaning, plasma cleaning or a combination thereof.

9. The method as claimed in claim 1, further having a step of allowing powder material to be desorbed at a high temperature in a vacuum before the step of applying powder material.

10. The method as claimed in claim 9, wherein the powder material is

11. The method as claimed in claim 4, further having a step of allowing powder material to be desorbed at a high temperature in a vacuum before the step of applying powder material.

12. The method as claimed in claim 11, wherein the powder material is desorbed at 800˜1200° C. in a vacuum of 10⁻¹˜10⁻⁵ torr for less than 5 hours.

13. The method as claimed in claim 1, wherein in the step of sequentially pre-pressing and sintering the spent target with the powder-filled layer, sintering comprises hot-press sintering, hot isostatic press (HIP) sintering, spark plasma sintering or a combination thereof.

14. The method as claimed in claim 4, wherein in the step of sequentially pre-pressing and sintering the spent target with the powder-filled layer, sintering comprises hot-press sintering, hot isostatic press (HIP) sintering, spark plasma sintering or a combination thereof.

15. The method as claimed in claim 1, wherein in the step of providing a spent target, the spent target contains precious metal.

16. The method as claimed in claim 1, wherein the spent target contains precious metal selected from the group consisting of ruthenium (Ru), platinum (Pt), palladium (Pd), silver (Ag), gold (Au), rhodium (Rh), iridium (Ir), osmium (Os) and an alloy thereof.

17. The method as claimed in claim 4, wherein the spent target contains precious metal selected from the group consisting of ruthenium (Ru), platinum (Pt), palladium (Pd), silver (Ag), gold (Au), rhodium (Rh), iridium (Ir), osmium (Os) and an alloy thereof.

18. A refurbished sputtering target comprises:
a spent target having
a mechanically treated backside;
an eroded side having at least one depleted region formed in the eroded side; and
a rim;
a powder-filled layer being at least formed on the eroded side as well as in the depleted region, allowing at least the backside of the spent target to expose from a bottom of the powder-filled layer and having a composition that is the same as the spent target.

19. The refurbished sputtering target as claimed in claim 18, wherein said spent target contains precious metal.

20. The refurbished sputtering target as claimed in claim 19, wherein said spent target contains precious metal selected from the group consisting of ruthenium (Ru), platinum (Pt), palladium (Pd), silver (Ag), gold (Au), rhodium (Rh), iridium (Ir), osmium (Os) and an alloy thereof.
